(19) United States
(12) Patent Application Publication
(10) Pub. No.: US 2005/0139867 A1
(43) Pub. Date: Jun. 30, 2005

(54) Field effect transistor and manufacturing method thereof

(76) Inventors: Shin-ichi Saito, Kawasaki (JP); Tadashi Arai, Kumagaya (JP); Digh Hisamoto, Kokubunji (JP); Ryuta Tsuchiya, Hachioji (JP); Hiroshi Fukuda, Kodaira (JP); Takahiro Onai, Kodaira (JP)

Correspondence Address: REED SMITH LLP;Suite 1400, 3110 Fairview Park Drive, Falls Church, VA, 22042, US

(21) Appl. No.: 10/933,338

(22) Filed: Sep. 3, 2004

(30) Foreign Application Priority Data
Dec. 24, 2003 (JP) JP2003-426172

(51) Int. Cl. H01L 29/76; H01L 21/335

(52) U.S. Cl. 257/213; 438/142

(57) ABSTRACT

The Mott transistor capable of operating at a room temperature can be realized by using a self-organized nanoparticle array for the channel portion. The nanoparticle used in the present invention comprises metal and organic molecules, and the size thereof is extremely small, that is, about a few nm. Therefore, the charging energy is sufficiently larger than the thermal energy k_{B}T=26 meV, and the transistor can operate at a room temperature. Also, since the nanoparticles with a diameter of a few nm are arranged in a self-organized manner and the Mott transition can be caused by the change of a number of electrons of the surface density of about 10¹² cm⁻², the transistor can operate by the gate voltage of about several V.

### CROSS-REFERENCE TO RELATED APPLICATION

The present application claims priority from Japanese Patent Application JP 2003-426172 filed on Dec. 24, 2003, the content of which is hereby incorporated by reference into this application.

### TECHNICAL FIELD OF THE INVENTION

The present invention relates to a field effect transistor and a manufacturing method thereof. More specifically, the present invention relates to a new-type field effect transistor and a manufacturing method thereof, which can simultaneously achieve the low off-current and the high on-current by using the self-organized nanoparticle array as a material of a channel portion and using the metal-insulator transition (Mott transition) as an operational principle thereof.

### BACKGROUND OF THE INVENTION

The technology for an integrated circuit using silicon has been developing at an amazing pace. With the development of the technology for scaling down, the size of the elements has been reduced and the number of elements integrated in one chip has been increased. As a result, advanced functions can be achieved. At the same time, the improvement of the current drive capability and the reduction of the load capacity resulting from the scaling down of the elements make it possible to achieve the high-speed operation. The current mainstream of the silicon device is the CMOSFET (Complementary Metal Oxide Semiconductor Field Effect Transistor), and a CMOSFET with the channel length of 0.1 μm or shorter is already commercially available.

However, the scaling down of the CMOSFET is approaching its limit. Actually, with reference to the International Technology Roadmap for Semiconductor (ITRS) Sematech (2002), it is expected that most of the technologies to be required in 2005 to 2010 can be hardly achieved, and the further scaling down of the CMOS cannot be achieved due to its physical limit as well as economic problems such as yield and cost. Therefore, it is believed that it is difficult to achieve the next generation of the 45 nm technology node which is expected to be put into practical use in about 2010.

One of its causes is the so-called short channel effect. The short channel effect is a physical phenomenon which becomes apparent due to the reduction of the channel length of a MOSFET (Metal Oxide Semiconductor Field Effect Transistor). More specifically, with the reduction of the channel length, a source diffusion layer and a drain diffusion layer come closer to each other. Since the pn junction exists at the boundary between the source and drain diffusion layers, depletion layers are formed at the respective boundaries thereof. When the channel length is reduced, the depletion layers also come close to each other, and in the worst case, the depletion layers are connected and the phenomenon called punch through occurs. As a result, the leakage current flows between the source and drain even when the MOSFET is in an Off state. Even when the depletion layer of the source and the depletion layer of the drain are not connected completely, the leakage current is not negligible if the channel length is short. The leakage current can be reduced in some degree by controlling the impurity profile and using the SOI (Silicon on Insulator) substrate. However, such measures also have their limits. The short channel effect causes various problems resulting from the reduction of the controllability of the MISFET by the gate electrode, for example, the increase of the leakage current, reduction of the On/Off ratio of the current, and the increase of the threshold value.

In order to overcome the limits of the CMOS mentioned above, various attempts using the nano technology have been made. For example, the single-electron transistor, the resonant tunnel transistor, and the single-molecule transistor are known. From among them, the single-electron transistor and the single-molecule transistor are the ultimate low-power devices in which one electron or a few electrons are controlled by the gate voltage. Therefore, it is possible to reduce the leakage current in the Off state, whereas the drive current in the On state is also low. As a result, it is impossible to obtain the sufficient On/Off ratio. Also, since the resonant tunnel transistor uses the tunnel current passing through the insulating film, it is impossible to obtain the sufficient On/Off ratio. In addition, since the current value is changed exponentially even by the extremely slight difference of 0.1 to 1.0 nm in the thickness of the insulating film, a problem that the characteristics of the elements greatly differ between the devices occurs. Therefore, in order to replace the CMOSFET by the newly developed devices using the quantum effect, the further improvement of the device characteristics is desired.

Furthermore, as a device which attracts attention recently, the organic transistor has been studied. The organic transistor is a field effect transistor characterized in that organic semiconductors such as polythiophene and pentacene are used as the channel material. Since the technology for synthesizing the organic semiconductor materials has been developed drastically in recent years, the performance of the organic transistor has also been improved. Since the organic transistor can be formed on a flexible plastic substrate, it is possible to bend the substrate. Therefore, it is expected that the display using a thin and bendable plastic substrate like a sheet, that is, an electronic paper can be realized if the organic transistor can be combined with the organic EL (Electro-Luminescence) which is a light emitting element. However, although the mobility of about 1.0 cm²/Vs which is almost equivalent to that of amorphous silicon is required in order to drive the organic EL, the mobility of the current organic semiconductor is ten to hundred times smaller than this. Consequently, it is difficult to drive the organic EL with the current organic semiconductor. As described above, since the mobility of the organic semiconductor is small, the performance of the organic semiconductor is insufficient as the post-CMOSFET unfortunately.

A device called a Mott transistor has been attracting attention as another device developed to be the post-CMOSFET. This is a type of a field effect transistor in which a material showing the metal-insulator transition called the Mott transition is used to realize the low Off-leakage current in the state of the insulator and the high On-driving current in the state of the metal. For example, Japanese Patent Laid-Open Application No. 11-163365 discloses the method for forming the Mott transistor in which BEDT-TTF which is an organic molecule and La₂₋ₓSrₓCuO₄ which is a high-temperature superconductor are used as channel materials.

Here, the Mott transition will be described in brief. Transition metal oxide such as NiO which is metal in the usual band theory is an insulator therein. Since the outermost electrons belong to the d orbit in the transition metal oxide, the electrons are strongly localized at each atom. As a result, the interaction between the electrons is strong. FIG. 2 shows the state of hopping of the electrons 2 through the sites 1. In this case, the site 1 indicates one nucleus when the Mott transition material is the transition oxide, and the site 1 indicates one organic molecule when the Mott transition material is the organic molecule. When the degeneracy of the orbit is not considered for simplifying the description, since the electrons have the degree of freedom of the spin degeneracy, up to two electrons enter each site 1. The coulomb interaction acting between the electrons becomes strongest when two electrons enter the same site. Since the energy is increased when the coulomb repulsive force works, the electrons keep away from each other and move around so as not to enter the same site. In the case where the number of electrons is smaller than that of the sites as shown in FIG. 2, the electrons can keep away from each other. Therefore, the influence of the interaction between electrons is small even if the strong interaction works between the electrons, and the electrons can hop through the atoms relatively freely. In this case, the system behaves like a metal. However, in the case where the number of electrons is almost equal to that of the sites as shown in FIG. 3, the influence of the interaction between electrons is very strong, and the electrons cannot move freely. In this case, the system behaves like an insulator though electrons to be carriers are present. The system where the electrons are strongly influenced by the adjacent electrons due to the strong interaction between the electrons is called the strong correlation electron system. The basic concept of the above-described Mott transistor is to change the insulator state in FIG. 3 to the metal state in FIG. 2 by controlling the number of electrons by the gate voltage.

The concept of the Mott transition is quite common, and the suggestion that the Mott transition can be found not only in some kind of transition metal oxide and the organic materials present in nature but also the artificial lattice obtained by processing semiconductor such as Si and GaAs was made in Appl. Phys. Lett., vol. 78, p. 3702 to 3704 (2001). It is well known that one quantum dot formed artificially behaves like an atom and the two quantum dots made close to each other behave like an artificial molecule. The suggestion to create the artificial atoms by forming a large number of such artificial quantum dots by using the fine processing technology is made in the letter mentioned above. This corresponds to creating the artificial crystal by the combination of the atoms shown in the periodic table. The letter also describes that the strong correlation electron system can be produced by forming the artificial lattice in a leticulate form by the sub-micron processing to In_{0.72}Ga_{0.28}As, and the phase transition to the ferromagnetic state can be achieved.

Also, Science, vol. 277, p. 1978 (1997) reports that the metal-insulator transition can be caused by using nanoparticles of metal. According to this, the single film made from nanoparticles of silver behaves like a metal when the length between the adjacent nanoparticles is short and behaves like an insulator when the length is long. This change is confirmed by changing the length between the particles by applying the pressure to the metal nanoparticles floating on the water. However, when the nanoparticles are formed on a substrate made of silicon or plastic, it becomes difficult to change the length between the nanoparticles. Therefore, the method for actually applying it to a device is not described.

### SUMMARY OF THE INVENTION

As described above, the Mott transistor is expected to be a post-CMOSFET. For its achievement, however, there are various problems to be solved.

For example, various attempts to cause the phase transition by the field effect in a strong correlation electron system such as the transition metal oxide is described in Nature, vol. 424, p. 1015 (2003). This document indicates that there is a possibility that the electron state can be significantly changed by using the field effect, for example, the change of superconduction and the giant magnetoresistance. However, it is quite difficult to actually change the physical properties of the bulk by the field effect, and there has been no report that the phase transition is clearly observed by using the Mott transistor.

The inventors of the present invention have examined why the conventional Mott transistor using Mott transition materials such as transition metal oxide and organic molecule crystal does not operate properly. As a result, it is found out that the largest problem is the extremely large change of the electron density which is required to cause the Mott transition. Since the length between atoms is about 0.1 to 1.0 nm, the atom density per unit area is about 10¹⁵ cm⁻². It is necessary to change the electron density at least about 10% per one site in order to cause the Mott transition and change the state of FIG. 3 to the state of FIG. 2. That is, when the conventional Mott transistor in which the site 1 represents one atom or one molecule is operated, the extremely large change in electron density of about 10¹⁴ cm⁻² is required. This is ten times larger than 10¹³ cm⁻² which is the number of electrons controllable by the gate voltage when the best gate insulating film in the current technology is used. Therefore, it is necessary to apply the extremely large gate voltage of about 100 V in order to cause the Mott transition of the system, and the dielectric breakdown occurs before the Mott transition is caused.

On the other hand, the suggestion to cause the Mott transition in an artificial lattice formed by using the fine processing technology is made. However, the minimum processing dimension in the fine processing technology is relatively large, that is, about 100 nm. Therefore, the size of the quantum dots is reduced and the energy scale associated with charging becomes small. As a result, the phase transition temperature at which the ferromagnetic transition and metal-insulator transition are caused is significantly reduced to about several k (−270° C.). Therefore, it is extremely difficult to apply it to the actual device. More specifically, the Mott transistor in which the site 1 is formed by the fine processing technology can be operated at only extremely low temperature. The site with the minimum processing dimensions of about 20 nm can be formed when the state-of-the-art fine processing technology of Si is used. However, it is nevertheless difficult to operate it at the room temperature. In order to operate it at the room temperature, it is necessary to make the charging energy larger than the thermal energy k_{B}T (k_{B} is Boltzmann coefficient and T is temperature.) generated by the thermal fluctuation. Since k_{B}T is about 26 meV at room temperature, the particle diameter of the quantum dot of about 10 nm or smaller, more preferably, about 5 nm or smaller is required to make the charging energy larger than it. It is quite difficult to fabricate such a minute structure by the fine processing technology.

Therefore, the effective method for operating the Mott transistor, which is one of the promising candidates of the post-CMOSFET, at a room temperature is not known yet.

In such a circumstance, an object of the present invention is to provide a Mott transistor and a manufacturing method thereof, which can operate at a room temperature by applying a gate voltage of about a few V with using the method easily realized by the current technology. Another object of the present invention is to provide a Mott transistor which can be formed on a flexible substrate at low cost and a manufacturing method thereof.

For the achievement of the above-described objects, the present invention uses the nanoparticle array for the channel. In this manner, it is possible to provide a Mott transistor which can operate at a room temperature and a manufacturing method thereof. As the process for forming the nanoparticle array, a phenomenon called the self-organization is used. The self-organization indicates the phenomenon in which a well-organized structure is formed spontaneously, and the nanoparticle array indicates an array in which particles with a diameter of about a few nm are orderly arranged. The nanoparticles used in the present invention are composed of the metal at a central portion and organic molecules which cover the central portion, that is, the central portion of metal is covered with organic molecules. These organic molecules prevent the aggregation of the metal in the adjacent nanoparticles so as not to enlarge the metal portion. As the metal in the central portion, aluminum, tin, silicon, cadmium, and selenium in addition to precious metals such as gold, silver, copper, and platinum are available. Also, as the organic molecules which cover the central portion, the organic compound with a thiol group as shown in the chemical formulas 1 and 2 is effective. 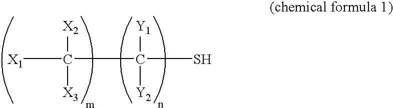
(X1, X2, X3, Y1, and Y2 are hydrogen, hydroxyl group, thiol group, amino group and the like, respectively, and the same one or the different ones are available.)
   Z-SH (chemical formula 2)
(Z is an aromatic ring such as benzene or a multi-ring compound, which may have a substituent.) When the nanoparticles are formed on a substrate, the nanoparticles form a close-packed structure and are self-organized. In addition, since the particle diameter of the central portion of the nanoparticles is quite small, that is, 10 nm or smaller, the charging energy is large enough to observe the charging effect of the single electron to the nanoparticles even at a room temperature. Furthermore, since the self-organized nanoparticle array is used as the channel material, the effective mobility larger than that of the conventional organic transistor can be obtained. Therefore, it is possible to provide a transistor which can be formed on a flexible substrate at low cost and a manufacturing method thereof.

As described above, in order to put the Mott transistor to practical use, it is necessary to cause the Mott transition by applying the gate voltage of about several V. This can be achieved if the Mott transition can be caused by changing electron density from 10¹² cm⁻² to 10¹³ cm⁻². This can be achieved if the nanoparticles with a diameter of a few nm are arrayed in a self-organized manner. Since the surface density is about 10¹³ cm⁻² when the nanoparticles with a diameter of a few nm are arrayed in a self-organized manner, it is possible to cause the Mott transition by the change of the number of electrons of about 10¹² cm⁻² which is 10% of 10¹³ cm⁻². Also, since the charging energy of the nanoparticles is in the range of several tens meV to several hundreds meV, it is sufficiently larger than the energy k_{B}T=26 meV generated by the thermal fluctuation, and thus, it becomes possible to operate the Mott transistor at a room temperature. More specifically, by using the chemically synthesized nanoparticles as the site 1, the two objects that cannot be achieved in the conventional Mott transistor, that is, the low voltage operation and the room-temperature operation can be achieved for the first time. In addition, since it is possible to cause the metal-insulator transition simply by controlling the number of carriers by gate voltage without changing the length between the nanoparticles, the Mott transistor can be operated on any types of substrate.

In addition, the Mott transistor according to the present invention has advantages not only in the operational principle of the device but also in its manufacturing method. More specifically, the minute nano structure as described above cannot be formed by the fine processing technology using the lithography. However, if the chemical method for forming the nanoparticles which has been developed recently is used, a large quantity of the nanoparticles can be formed and the nanoparticles can be arrayed in a self-organized manner.

In the Mott transistor according to the present invention, the self-organized nanoparticle array is used for the channel and the carrier density thereof is controlled by the gate voltage. By doing so, the phase transition between the metal state and the insulator state can be caused. As a result, it is possible to simultaneously achieve the high On-driving current and low Off-leakage current.

In the field effect Mott transistor using the self-organized nanoparticle array according to the present invention, the high driving current in the metal state and the low Off-leakage current in the insulator state can be achieved simultaneously. Since the pn junction is not provided between the source-drain electrodes and the self-organized nanoparticle array to the channel, the short channel effect can be prevented, and the scaling down beyond the limit of the conventional CMOSFET can be realized. Since the high-performance Mott transistors can be integrated on a flexible plastic substrate, it is possible to drive the organic EL which cannot be driven by the conventional organic transistors. Consequently, it is possible to provide the transistors to be an essential technology in the ubiquitous society, which can be formed on an optional substrate. In addition, since the single crystal silicon substrate is not used, it is possible to manufacture the device at low cost.

### BRIEF DESCRIPTIONS OF THE DRAWINGS

FIG. 1 is cross-sectional view of a completed semiconductor device according to the first embodiment of the present invention;

FIG. 2 is a schematic diagram showing the state where Mott (metal-insulator) transition material is in a metal state;

FIG. 3 is a schematic diagram showing the state where Mott (metal-insulator) transition material is in an insulator state;

FIG. 4 is a cross-sectional view of a gold nanoparticle used in the present invention;

FIG. 5 is a cross-sectional view showing a manufacturing process of the Mott transistor according to the first embodiment of the present invention;

FIG. 6 is a cross-sectional view showing a manufacturing process of the Mott transistor according to the first embodiment of the present invention;

FIG. 7 is a cross-sectional view showing a manufacturing process of the Mott transistor according to the first embodiment of the present invention;

FIG. 8 is a cross-sectional view showing a manufacturing process of the Mott transistor according to the first embodiment of the present invention;

FIG. 9 is a cross-sectional view of a completed semiconductor device according to the first embodiment of the present invention;

FIG. 10A to FIG. 10D are explanatory diagrams for the method of forming an LB film;

FIG. 11 is a diagram showing the completed Mott transistor seen from above according to the first embodiment of the present invention;

FIG. 12 is a cross-sectional view showing a CMOS circuit using the Mott transistors according to the first embodiment of the present invention;

FIG. 13 is a wiring diagram of the Mott transistor seen from above according to the first embodiment of the present invention;

FIG. 14 is a circuit diagram of the laminated Mott transistor according to the first embodiment of the present invention;

FIG. 15 is a cross-sectional view of the Mott transistor formed on the CMOS circuit according to the first embodiment of the present invention;

FIG. 16 is a graph showing the electric characteristics of the Mott transistor according to the first embodiment of the present invention;

FIG. 17 is a graph showing the metal state of the self-organized nanoparticle array;

FIG. 18 is a graph showing the insulator state of the self-organized nanoparticle array;

FIG. 19 is a cross-sectional view showing a manufacturing process of the Mott transistor according to the second embodiment of the present invention;

FIG. 20 is a cross-sectional view showing a manufacturing process of the Mott transistor according to the second embodiment of the present invention;

FIG. 21 is a cross-sectional view showing a manufacturing process of the Mott transistor according to the second embodiment of the present invention;

FIG. 22 is a cross-sectional view of a completed Mott transistor according to the second embodiment of the present invention;

FIG. 23 is a graph showing the electric characteristics of the Mott transistor according to the second embodiment of the present invention;

FIG. 24 is a cross-sectional view showing a manufacturing process of the field effect transistor according to the third embodiment of the present invention;

FIG. 25 is a drawing showing the completed field effect transistor seen from above according to the third embodiment of the present invention; and

FIG. 26 is a cross-sectional view of an integrated circuit formed on a flexible substrate.

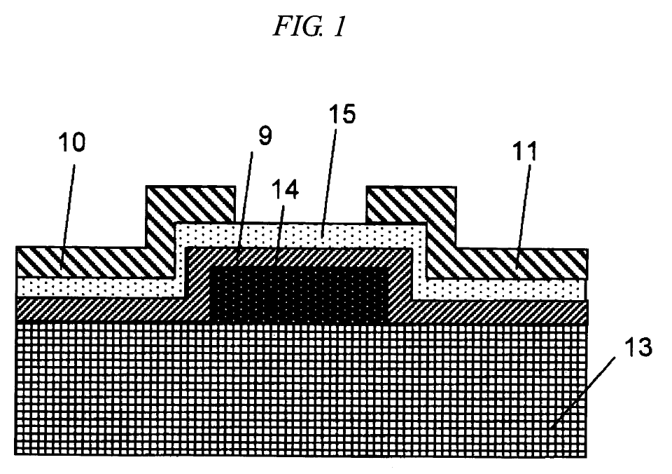

### DESCRIPTIONS OF THE PREFERRED EMBODIMENTS

Hereinafter, the present invention will be described in detail based on the embodiments. The description will be made with reference to the accompanying drawings so as to facilitate the understanding thereof. In the drawings, the principal part is enlarged. It is needless to say that the materials, conductivity, and the conditions in the manufacture are not limited to those in the description of the embodiments, and various modifications can be made within the scope of the present invention.

### First Embodiment

The method of synthesizing the nanoparticles used for a channel portion of the Mott transistor according to the present invention will be described. First, hydrogen tetrachloroaurate (III) tetrahydrate of 0.31 g is dissolved into the water of 30 ml. Then, toluene of 80 ml is added to the solution and tetra-n-octyl ammonium bromide of 2.2 g is added thereto. Thereafter, the solution is stirred for an hour at a room temperature. Then, 1-dodecanethiol of 170 mg is dropped slowly to the solution, and the solution is stirred for an hour. Meanwhile, sodium borohydride of 0.38 g is dissolved into the water of 25 ml and this is dropped into the above-mentioned solution in 30 minutes, and the resulting solution is stirred for four hours. The solution is separated and an organic layer is concentrated to 10 ml. Then, ethanol of 400 ml is added thereto and the resulting solution is left sitting for 50 hours at −18° C. Thereafter, it is dried under the reduced pressure after removing the supernautant liquid. In this manner, gold nanoparticles in dark brown of 0.21 g whose surface is protected by dodecanethiol can be obtained. The average particle diameter of the central portion of the nano-fine particles is 3.6 nm.

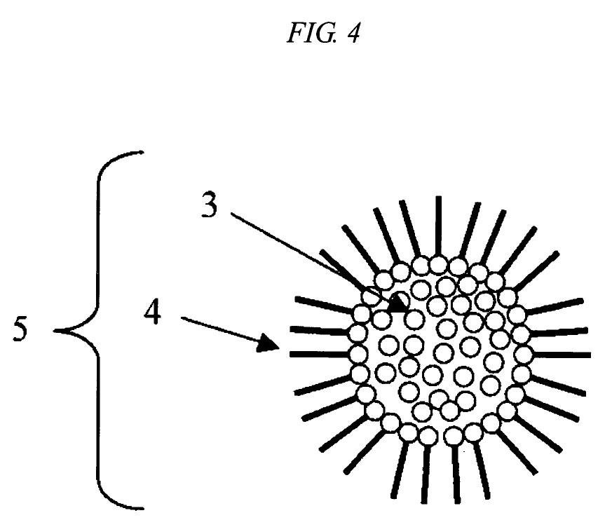

The gold nanoparticle 5 formed in the manner described above is shown in FIG. 4. In the gold nanoparticle 5, tens or hundreds of gold atoms are aggregated to the central portion, and organic compound 4 is chemically bonded to the periphery thereof. It is necessary that the diameter of the gold particle is set to 10 nm or smaller, more preferably, 5 nm or smaller so as to make the charging energy sufficiently larger than the thermal energy. It is confirmed that the nanoparticles with a diameter small enough to satisfy the above-described conditions can be synthesized by using the synthesizing method according to this embodiment. In this embodiment, sulfur atoms of thiol group and the gold atoms are bonded by the thiol group of the dodecanethiol, and the surface of the gold atoms is covered with the mono layer of the molecules of the dodecanethiol.

In the above-described example, gold is used as the material of the central portion of the nanoparticles. However, other materials including precious metals such as silver and platinum, metals such as copper, aluminum and tin and semiconductors such as silicon, germanium, cadmium, and selenium can be used as the constituent atoms. The reason why gold is used as the material of the central portion is because the bonding to the thiol groups is relatively strong in comparison to other materials and dodecanethiol having thiol group can easily cover the surface of the gold atoms. Therefore, the gold nanoparticles can be formed with good reproducibility and can be formed easily.

For example, silver nanoparticles in dark brown of 0.15 g whose surface is protected by dodecanethiol can be obtained in the same process as that of the synthesizing method for forming the nanoparticles described above except that silver perchlorate (I) of 0.19 g is used instead of hydrogen tetrachloroaurate (III) tetrahydrate of 0.31 g. The average diameter of the silver nanoparticles is 4.0 nm. No significant difference is observed in the device characteristics described later between the case of using the silver nanoparticles and the case of using the gold nanoparticles. Since the silver is not expensive in comparison to gold, the material cost can be reduced when silver is used as a material of the central portion instead of gold and thus silver is suitable for the mass production.

Alternatively, gold nanoparticles in dark brown of 2.3 g whose surface is protected by 2.5-dimethylthiophenol can be obtained in the same process as that of the synthesizing method for forming the nanoparticles described above except that 2.5-dimethylthiophenol of 232 mg is used instead of 1-dodecanethiol of 170 mg. The average diameter of the central portion of the gold nanoparticles is 3.3 nm. When dimethylthiophenol is used instead of dodecanethiol, the length between the surfaces of the central portions of the gold nanoparticles can be reduced and thus the charge can be moved more easily between the gold nanoparticles.

Alternatively, it is also possible to use two or more kinds of metal atoms to form the metal nanoparticles. In this case, hydrogen tetrachloroaurate (III) tetrahydrate of 0.15 g and hexachloroplatinate hydrate of 0.15 g are dissolved into the water of 30 ml. Then, toluene of 80 ml is added to the solution and tetra-n-octyl ammonium bromide of 2.2 g is added thereto. Thereafter, the solution is stirred for an hour at a room temperature. Then, 1-dodecanethiol of 170 mg is dropped slowly to the solution and the solution is stirred for an hour. Meanwhile, sodium borohydride of 0.38 g is dissolved into the water of 25 ml and this solution is dropped into the above-mentioned solution in 30 minutes, and the resulting solution is stirred for four hours. The solution is separated and an organic layer is concentrated to 10 ml. Then, ethanol of 400 ml is added thereto and the resulting solution is left sitting for 50 hours at −18° C. Thereafter, it is dried under the reduced pressure after removing the supernautant liquid. In this manner, platinum nanoparticles in dark brown of 0.21 g in which the central core is coated with gold and whose surface is protected by dodecanethiol can be obtained. The average diameter of the central portion of the nanoparticles is 1.8 nm. In this embodiment, sulfur atoms of thiol group and the gold atoms are bonded by the thiol group of the dodecanethiol, and the surface of the gold atoms is covered with the mono layer of the molecules of the dodecanethiol. In the case where two or more kinds of metal atoms are mixed, it is possible to form the nanoparticles with smaller diameter than that formed of a single metal such as gold and silver. Therefore, it is possible to further increase the charging energy of the nanoparticles. Consequently, when the material obtained by mixing two or more kinds of metal atoms is used for the channel portion of a Mott transistor, it is possible to operate the Mott transistor at a room temperature or a higher temperature.

Next, a substrate used to form the Mott transistor is prepared. In this embodiment, a silicon substrate is used for the simplification of the description. However, when a plastic substrate or the like is used as the substrate, it is possible to fabricate the integrated circuit 27 including the Mott transistors on a flexible substrate 26 which is bendable as shown in FIG. 26. As mentioned above, the integrated circuit board which is bendable like a sheet can be an essential technology in the ubiquitous society. The effect of using the silicon substrate as in this embodiment is that the conventional CMOS device and the Mott transistor can be integrated on the same chip as described later. Therefore, the Mott transistor can inherit the techniques developed in the conventional silicon technology such as process, design, layout, and circuit. Also, when the SOI substrate is used, it is possible to integrate the SOI device and the Mott transistor on the same chip.

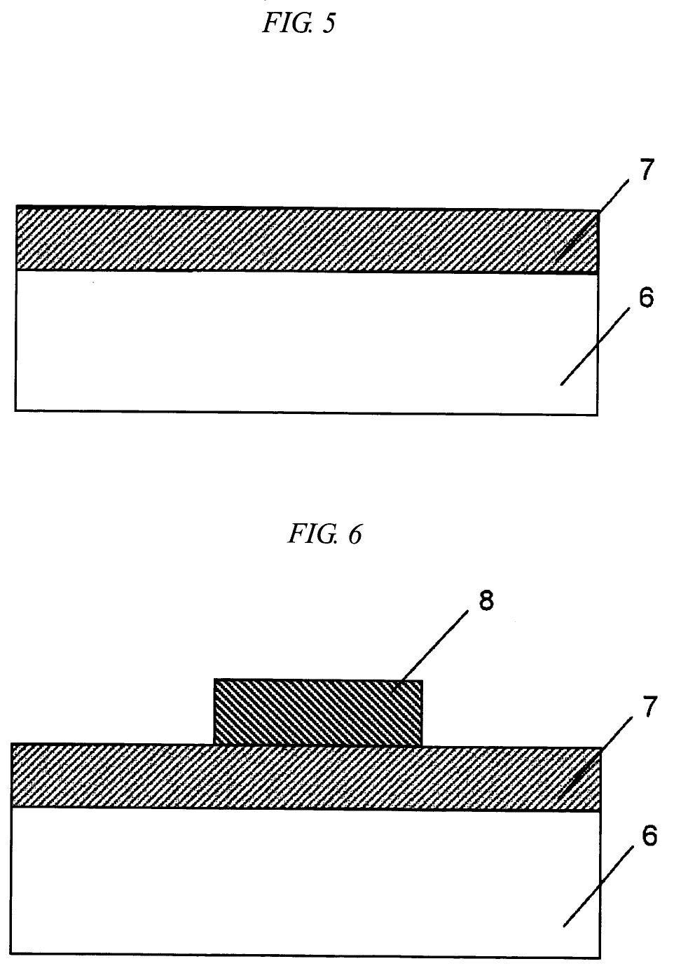

Next, as shown in FIG. 5, the surface of the silicon substrate 6 used in this embodiment is oxidized to form a silicon dioxide insulating film 7 with a thickness of 200 nm for device isolation. Subsequently, a polysilicon film with a thickness of about 200 nm doped to n+ conductivity is deposited on the whole surface of the silicon dioxide insulating film 7. Thereafter, the polysilicon film is processed into a desired pattern by the photolithography and the dry etching technique to form the n type gate electrode 8 as shown in FIG. 6. Another gate electrode with p type conductivity to change the threshold voltage is also formed. In this case, it is possible to reduce the threshold voltage of the Mott transistor by about 1 V. In addition, it is also possible to use metal such as gold and aluminum having different work function for the gate electrode. The material of the gate electrode can be optionally selected depending on the target design of the threshold voltage.

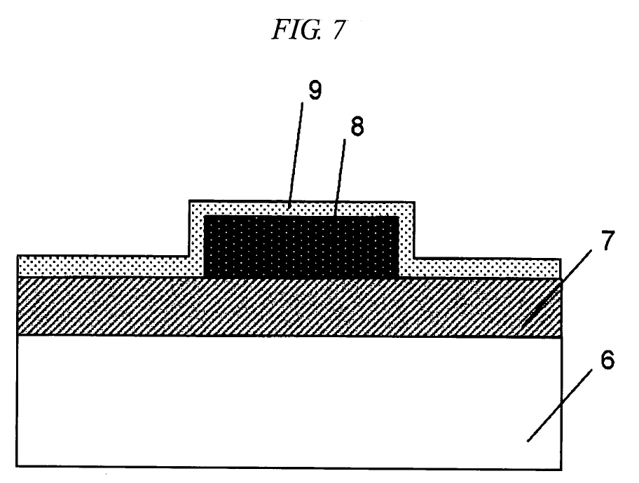

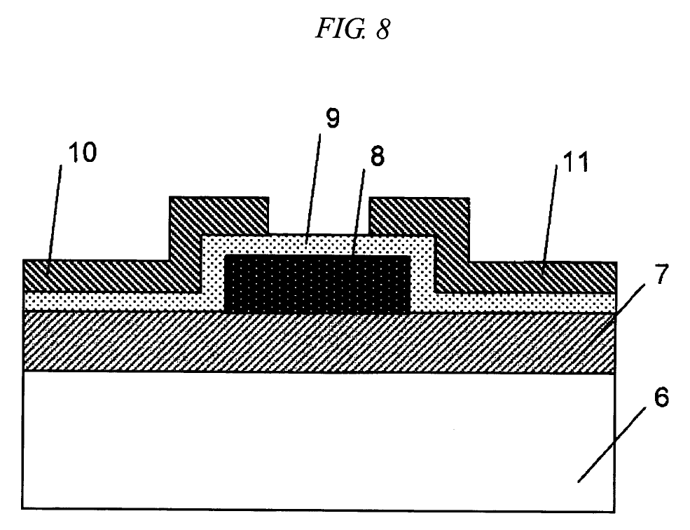

Next, a silicon dioxide insulating film 9 with a thickness of 20 nm is deposited on the whole surface as shown in FIG. 7. Then, a resist with a thickness of 1 μm is coated on the whole surface, and then, the resist is processed into a desired pattern by the photolithography. Thereafter, gold with a thickness of 100 nm is evaporated on the whole front surface. Then, the sample is placed into acetone and stirred by the ultrasonic wave to remove the resist. By doing so, gold is lifted off and the gold source electrode 10 and the gold drain electrode 11 are formed as shown in FIG. 8. The channel length L of the Mott transistor formed in this embodiment is 20 μm and the width W thereof is 20 μm.

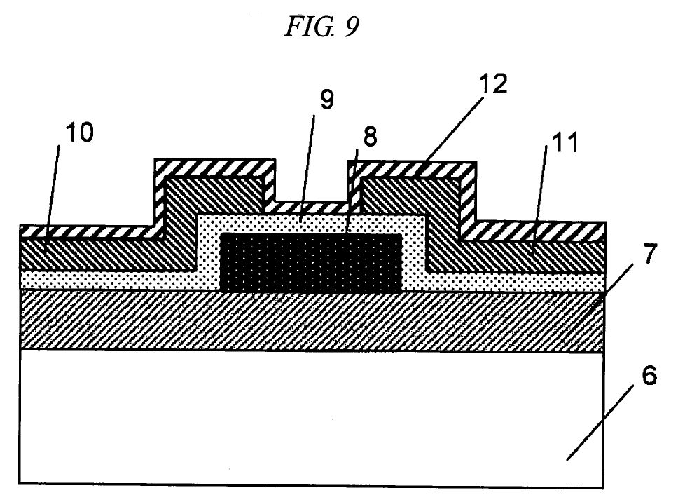

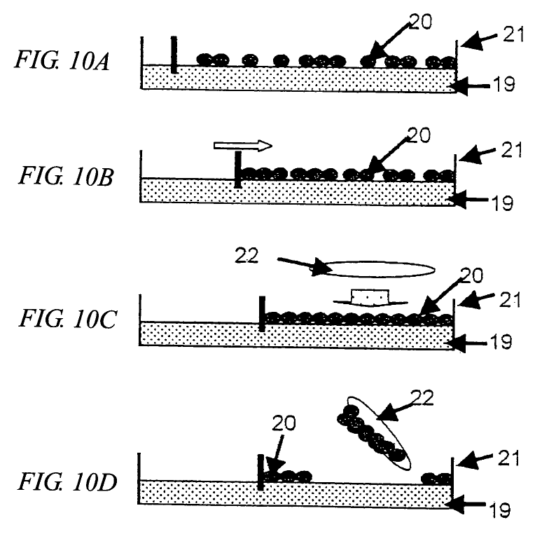

Next, the gold nanoparticles are dissolved into an organic solvent (toluene) and coated to the whole surface by using a spin coating machine so as to have a thickness of about 100 nm. By doing so, the self-organized nanoparticle array 12 is formed and the Mott transistor is completed as shown in FIG. 9. In order to reduce the leakage current in an Off state, it is desired that the self-organized nanoparticle array 12 has a small thickness. Ideally, a single layer (mono layer) is desired. Actually, when the self-organized nanoparticle array 12 is formed as a Langmuir Blodgett film (LB film), it is possible to form the self-organized nanoparticle array 12 as a mono layer. When the self-organized nanoparticle array 12 is formed as a mono layer, the Off-leakage current of the Mott transistor becomes minimum. FIG. 10 shows the method of forming the LB film mentioned here. First, as shown in FIG. 10A, ultrapure water 19 is supplied to fill a bath 21, and the gold nanoparticles 2 dissolved in chloroform are dropped onto the ultrapure water by using a microsyringe so as to cover the surface of the water. Then, as shown in FIG. 10B, nano-fine particles 20 on the surface of the water are moved from one side and densely concentrated on the surface of the ultrapure water 19 to form the LB film. Thereafter, as shown in FIG. 10C, a substrate 22 on which the LB film of the nano-fine particles 20 is to be transferred is attached in parallel to the surface of the water. By doing so, the LB film of the gold nano-fine particles 20 is formed on the substrate 22. In this case, the gold nano-fine particles are dissolved into the chloroform to form the LB film. However, it is possible to add alcohol to this solution and also possible to use xylene and toluene as the solvent. The important reminders in this device manufacture will be shown below. Since the gold nanoparticles include organic matters, oxygen and moisture are easily adhered to the gold nanoparticles when they are in the air, and the device characteristics are degraded in many cases. Therefore, it is desired to form a passivation film which scarcely transmits oxygen and moisture. At this time, the device is heated to about 100° C. in vacuum or left as it is for four days so as to remove the adhered oxygen and moisture before forming the passivation film. By doing so, the device characteristics can be improved.

FIG. 11 is a plan view showing the Mott transistor seen from above. The nanoparticles 5 are orderly arrayed in a self-organized manner. However, although the self-organized nanoparticle array 12 behaves like the artificial crystal, the long-range order is not exactly maintained. That is, the size of the nanoparticles and the length between the nanoparticles are not uniform. The randomness due to the non-uniformity causes the electron scattering and resulting in the generation of the On current. Therefore, such non-uniformity should be reduced as small as possible. However, if the size of the nanoparticles is sufficiently small and the non-uniformity is within the range of several tens %, the charge effect to the nanoparticles can be sufficiently observed even at a room temperature, and it does not cause any problem to the operation of the Mott transistor. In addition, it is desired that the self-organized nanoparticle array includes no defect. The defect mainly indicates the state where some particles are attached together and some particles are not arrayed at the required positions in the close-packed structure. Even though some of these defects exist in the nanoparticle array, since the number of current paths between the source electrode and the drain electrode of the Mott transistor is almost infinite, the Mott transistor can be operated without any troubles. The close-packed structure mentioned in the present invention means the substantial close-packed structure, and the expression of close-packed structure is used even though some of these defects exist.

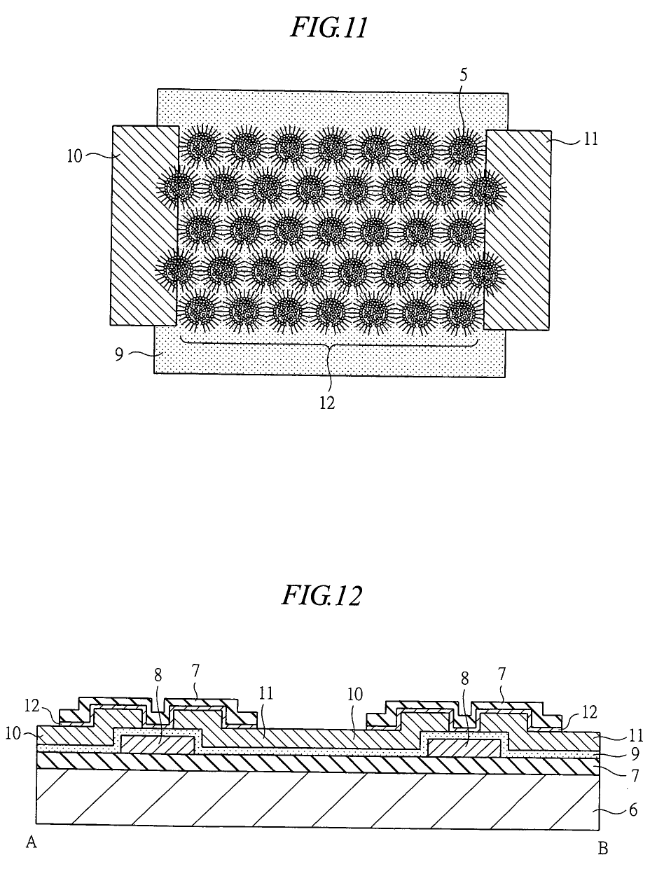

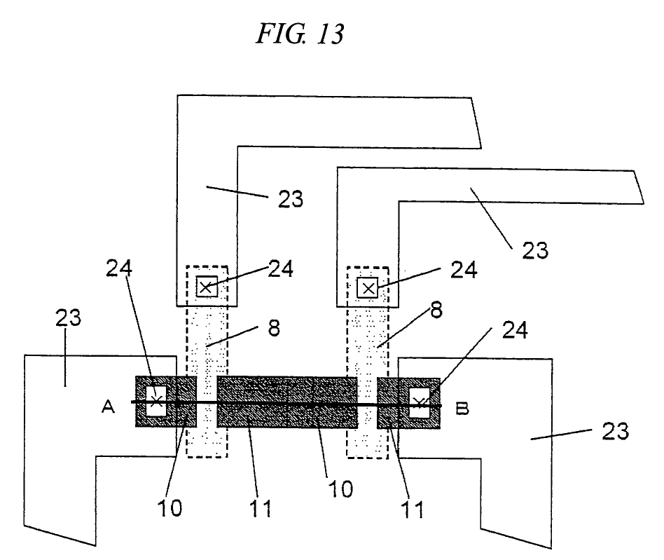

Subsequently, the process for the integration of the Mott transistors will be described. Since the process from FIG. 5 to FIG. 9 is identical except the step of FIG. 6 in which a plurality of gate electrodes 8 are formed, the description thereof will be omitted. In the state of FIG. 9, SiO₂ is deposited to 200 nm on the whole surface, and then, a part of SiO₂ is removed by using hydrofluoric acid with using a resist pattern formed by the photolithography as a mask so as to expose the self-organized nanoparticle array. Thereafter, the exposed part of the self-organized nanoparticle array 12 is removed by acetone. In this manner, a plurality of Mott transistors as shown in FIG. 12 can be formed. FIG. 12 is a cross-sectional view taken along the line A-B in FIG. 13, and the copper wirings 24 shown in FIG. 13 are omitted in FIG. 12. By exposing the surfaces of the gold source electrode 10 and the gold drain electrode 11, the contact region between the gold source electrode 10 and the wiring or between the gold drain electrode 11 and the wiring can be formed. Also, in the integrated Mott transistors shown in FIG. 12, the current does not pass through the substrate. Therefore, it is not necessary to form the device isolations which are formed in the silicon substrate in the case of the conventional CMOS. Consequently, it becomes possible to achieve the higher integration. FIG. 13 is a plan view showing the circuit seen from above in which the Mott transistors are integrated. Wirings 23 are electrically connected to the gate electrodes 8, the gold source electrodes 10, and the gold drain electrodes 11 via the copper wirings 24.

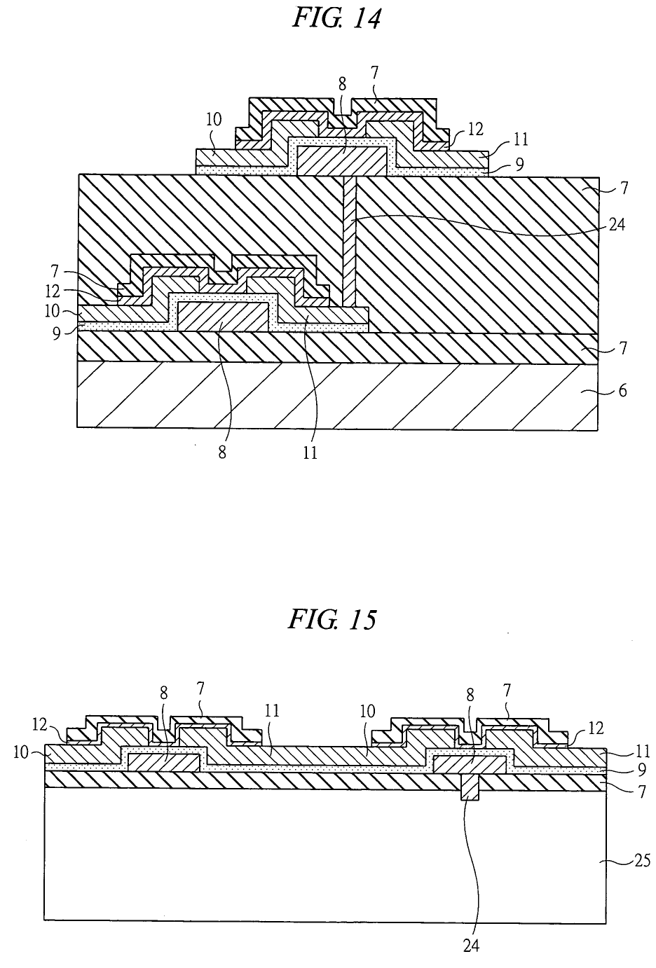

Also, as the method of forming another circuit, SiO₂ is deposited to 200 nm on the whole surface in the state of FIG. 12 and then the surface of SiO₂ is planarized by the CMP (Chemical Mechanical Polishing). Thereafter, the same process as that of forming the circuit in FIG. 12 is performed. By doing so, the circuit as shown in FIG. 14 in which the circuits composed of the Mott transistors are integrated can be formed. Since it is possible to arrange a plurality of Mott transistors in a thickness direction of the silicon substrate 6, it is possible to achieve the higher integration.

Furthermore, a substrate in which a CMOS circuit 25 is already formed on a silicon substrate is used instead of the silicon substrate 6 and the process for forming the circuit identical to that in FIG. 12 is performed to the wiring layer. By doing so, the circuit as shown in FIG. 15 in which the CMOS circuit and the circuit composed of the Mott transistor are formed on the same substrate can be obtained. Since it is possible to form the Mott transistor on the CMOS circuit 25, the CMOS circuit and the circuit composed of the Mott transistor can be formed together on the same substrate, and thus, the higher integration can be achieved. The CMOS circuit includes not only the circuit formed on the bulk of silicon but also the circuit formed on the SOI substrate.

This embodiment has described the case where the self-organized nanoparticle array 12 is formed on the whole upper surface of a substrate based on the method using the spin coating machine and the method of forming the LB film, and thereafter, the unnecessary part of the self-organized nanoparticle array is removed. However, it is also preferable to form the channel portion of the Mott transistor by dropping the self-organized nanoparticle array 12 in FIG. 12 onto only the region including the channel portion of the Mott transistor by using the method like the ink jet of the printing technology. According to this method, since the self-organized nanoparticle array is not formed on the whole upper surface of the substrate, the process for removing the unnecessary self-organized nanoparticle array which does not constitute the channel portion can be omitted. As a result, the process for manufacturing the integrated circuit of the Mott transistors can be facilitated.

The average particle diameter of the gold nanoparticles synthesized in this embodiment is 3.6 nm, the dispersion is 0.6 nm, and the average length between adjacent gold nanoparticles except the organic molecules is 2.0 nm. The minute nanoparticles like these allow the charging effect to be observed even at a room temperature. Also, since the conduction between the gold nanoparticles is made by the tunneling, it is desired that the length between the surfaces of the gold nanoparticles is at most 4.0 nm, and more preferably, it is 2.0 nm or shorter. In the gold nanoparticles produced in this embodiment, since the peripheral portion constituting the gold nanoparticles is a mono layer of the organic molecules, it is possible to satisfy this condition.

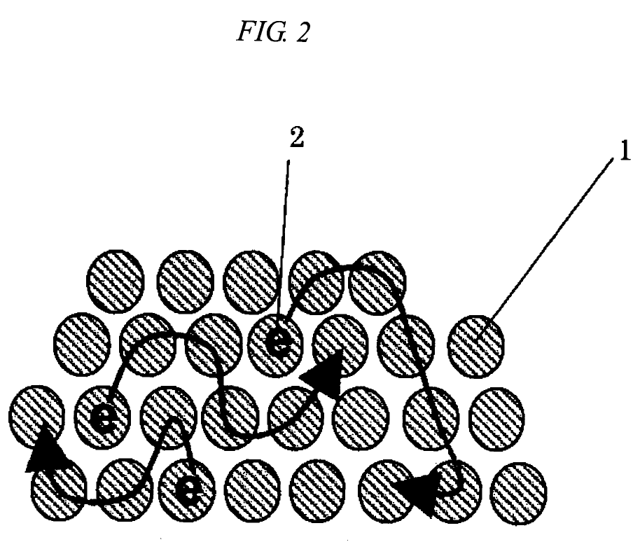

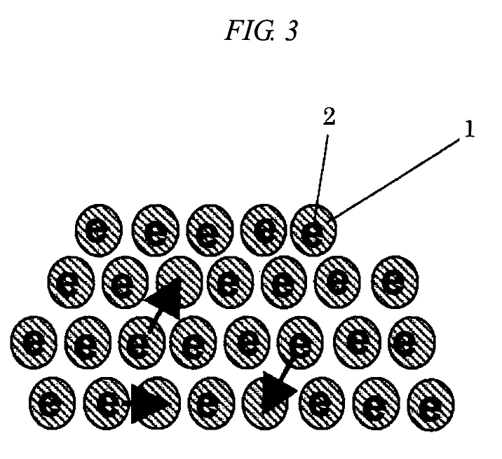

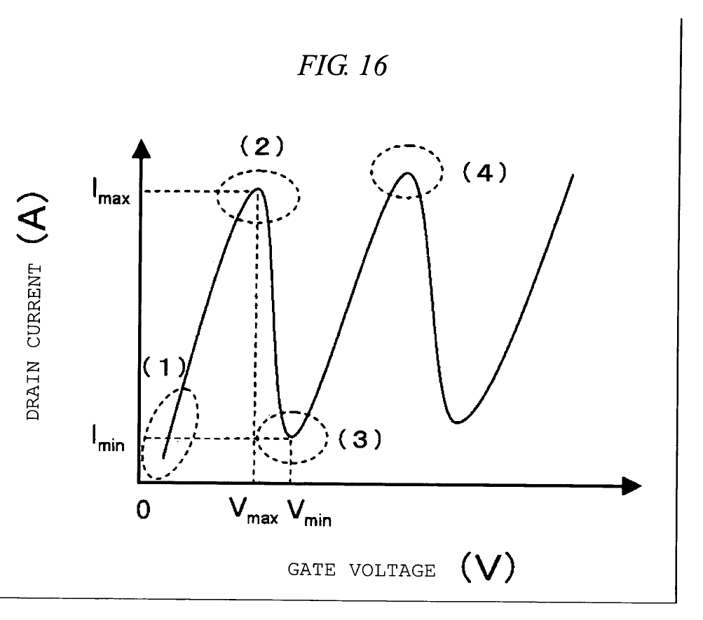

The device characteristics of the Mott transistor according to this embodiment are shown in FIG. 16. In this case, the potential difference of 20 V is applied between the source and drain. All of the electric measurements in the embodiments of the present invention are performed at a room temperature. When the gate voltage is gradually increased from the area (1), the drain current is increased, and the drain current starts to decrease after it reaches its maximum level in (2). Then, after the drain current reaches its minimum level in the area (3), it starts to increase again when the gate voltage is further increased, and it reaches its maximum level in (4). That is, it is observed that the drain current changes cyclically. When the voltage is not applied to the gate in the area (1), there is no electron charged in the nanoparticles. Therefore, it corresponds to the band insulator. On the other hand, when the gate voltage is gradually increased toward the area (1), the number of electrons is increased and the current is also increased correspondingly. The reason why the drain current is increased in the low-voltage area as described above is because the number of electrons is increased and the number of carriers which contribute to the conduction is increased. Because of the effect of the strong correlation system, the drain current starts to decrease. More specifically, the current is decreased as the metal state in FIG. 2 is changed to the insulator state in FIG. 3. This is due to the coulomb repulsion between the carriers caused as a result of the increase of the number of carriers by applying the voltage. Also, the state where one electron is placed at each nanoparticle corresponds to the Mott insulator, and at this time, the current value becomes minimum as shown by (3) in FIG. 16. The voltage Vmin at which the current becomes minimum is determined based on the dielectric constant and thickness of a gate insulating film and the density of the nanoparticles, and it is about 10 V in this embodiment. When the applied voltage is further increased, the average number of electrons in each nanoparticle reaches one or more, and the current value starts to increase again together with the increase of the number of carriers. The state where an odd number of carriers are present in each nanoparticle corresponds to the Mott insulator and the state where an even number of carriers are present in each nanoparticle corresponds to the band insulator. Therefore, since the current becomes minimum when the number of carriers per nanoparticle is an integer number, the current value changes cyclically together with the increase of the gate voltage.

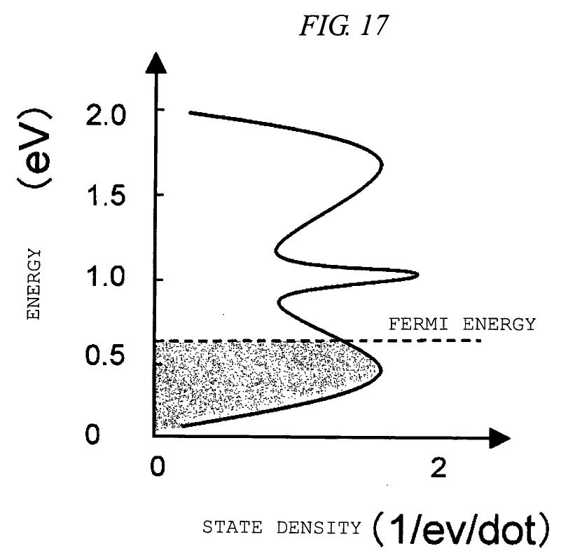

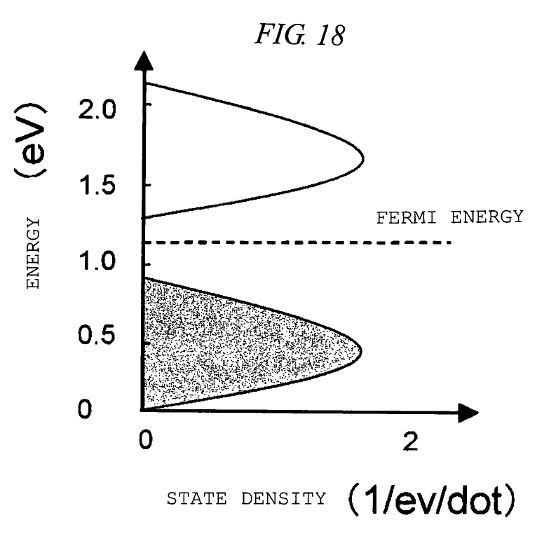

This change will be described with reference to FIGS. 17 and 18 showing the state density calculated by the use of simulation. Since the metal state in FIG. 2 has a sufficient number of electrons, the state density is present around Fermi energy as shown in FIG. 17, which shows the electric conduction like metal. This state corresponds to the metal state of the area (2) in FIG. 16. However, when the state is changed to the state of FIG. 3 by applying the gate voltage, the movement of the electrons is restricted due to the strong repulsive interaction between electrons, and the state density is not present around Fermi energy as shown in FIG. 18, which shows the electric conduction like insulator. This state corresponds to the Mott insulator state of the area (3) in FIG. 16. The change of the drain current resulting from the phase transition from metal to insulator corresponds to the change from the maximum drain current to the minimum drain current shown in FIG. 16. This change is sharper in comparison to that in the conventional CMOS because not only the number of carriers but also the state density are changed.

As described above, since the field effect transistor in which the self-organized nanoparticle array is used for the channel portion shows the negative resistance, it is suitably used to build a circuit such as an SRAM. Also, since it is possible to make the drain current increase or decrease for the increase of the gate voltage, such a field effect transistor can be used for both the nMOS and the pMOS by adjusting the work function of the gate even if the same self-organized nanoparticle array is used. In addition, since the Mott transistor based on this embodiment does not use the pn junction at the boundary between the source and drain electrodes and the channel, it is possible to prevent the short channel effect. Therefore, the electric characteristics thereof are not degraded even if the device is scaled down to the smaller size than the conventional CMOS. In addition, since the phase transition from the metal state to the insulator state is used as the operational principle, it is possible to achieve both of the extremely high On/Off ratio of 1 or higher and the high driving current in the metal state.

### Second Embodiment

In the above-described first embodiment, since the carriers are not doped into the nanoparticles before applying the gate voltage, the change form metal to insulator is observed when the gate voltage is increased. This second embodiment discloses the method as follows. That is, the doping to the self-organized nanoparticle array is performed in advance so as to achieve the normally off, and then, the Mott transistor is integrated on a flexible substrate.

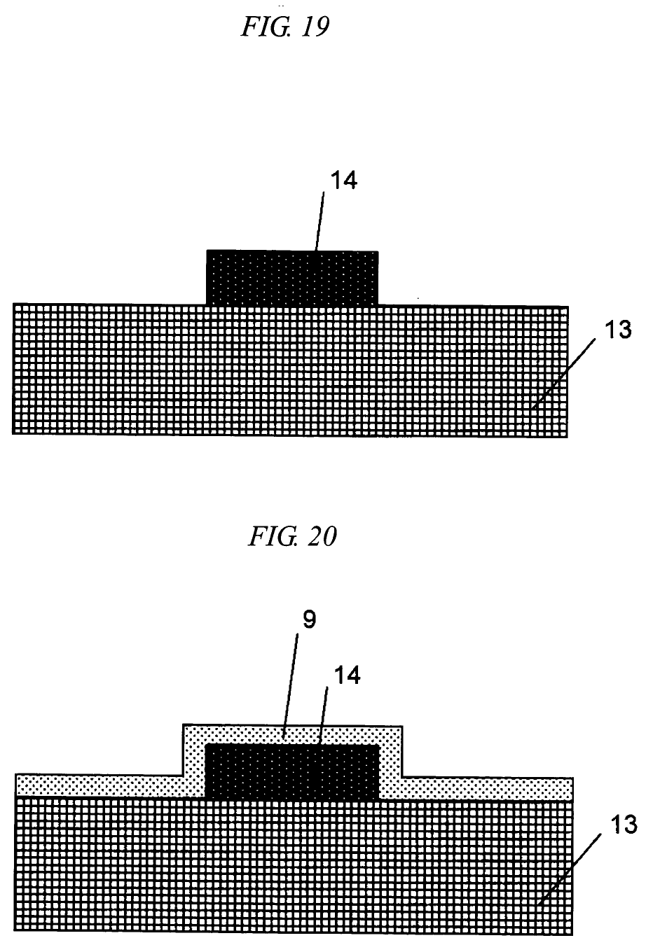

First, a flexible plastic substrate 13 is prepared and a gold gate electrode 14 is formed thereon by using the lift-off process as shown in FIG. 19. The flexible substrate is made of plastic and is cost effective in comparison to a single crystal silicon substrate. Therefore, it is possible to significantly reduce the cost for manufacturing the device.

Subsequently, a silicon dioxide gate insulating film 9 with a thickness of about 20 nm is deposited as shown in FIG. 20. Next, the nanoparticles are formed in the same manner as that of the first embodiment. The nanoparticles are dissolved into a solvent and a number of TTF (tetra-thiafulvalence) molecules almost equal to that of nanoparticles are dissolved into the solvent. When the nanoparticle array is formed by using this solution, the TTF molecules enter the spaces between adjacent nanoparticles. And then, charge is transferred from the TTF molecules to the gold nanoparticles, the TTF molecules are charged positive and the gold nanoparticles are doped with electrons. This is because the HOMO (highest occupied molecular orbital) of the TTF molecules is located at the position higher than the Fermi energy of gold. As described above, the material capable of implanting carriers by the ionization is called dopant or polarizing material. As a result of implanting an amount of polarizing material almost equal to that of the nanoparticles, the state corresponding to (3) in FIG. 16, that is, the Mott insulator state of FIG. 3 can be achieved even if no voltage is applied to the gate electrode. Therefore, it is possible to achieve the normally off. The dopant for implanting electrons is not limited to TTF molecules, and any materials are available if the HOMO of the organic molecules is larger than the Fermi energy of the materials which form the nanoparticles. Also, it is also possible to use a solution obtained by dissolving non-organic molecules such as Ce(CO₄)₂ which can be ionized relatively easily into a solvent containing the nanoparticles. In this case, since it is easily ionized, it effectively works as a dopant and can dope the electrons. In addition, it is also possible to dope the alkaline metal and alkaline earth metal. Also in this case, it effectively works as a dopant and can dope the electrons. Further, the doping amount is not limited to one per nanoparticle and is permissible if it is an odd number.

As another method for making the nanoparticle array be the Mott insulator without applying the gate voltage, there is the method for doping an odd number of holes into each nanoparticle instead of the electrons. In this case, any material are available if the HOMO of the organic molecules which are the polarizing material to be implanted is smaller than the Fermi energy of the material which forms the nanoparticles. Alternatively, when doping the holes, it is preferable to use a material having the work function larger than the energy obtained by measuring from the vacuum level to the Fermi energy of the material which forms the nanoparticles. For example, when gold is used as the nanoparticles, the holes are doped to the nanoparticles if the platinum ions are used as the polarizing material. Other materials such as I₂, Br₂, Cl₂, AsF₅, and BF₃ are also suitable for the hole dopants. By doping the holes, it is possible to form the Mott transistor in which the holes function as the carriers.

More specifically, the important point for achieving the normally off is that an odd number of carriers are doped in advance per nanoparticle before applying the gate voltage, and the kind of dopant and the polarity of the carriers are not particularly limited. Also, the difference between the number of TTF and the number of nanoparticles is ignorable if the difference in density is within the range of several %.

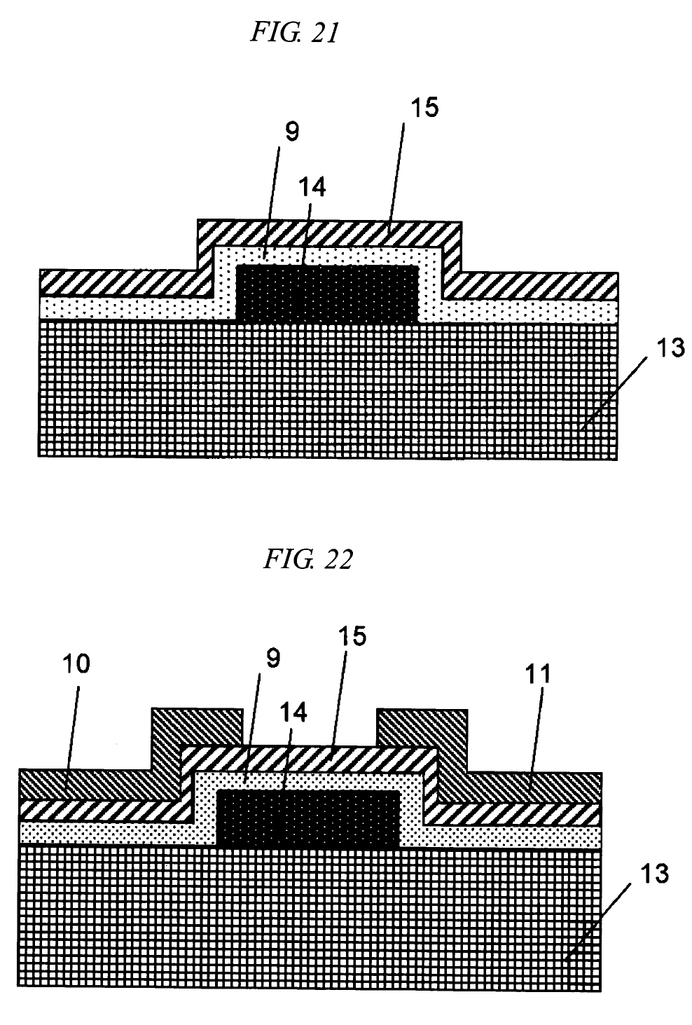

Next, a doped self-organized nanoparticle array 15 is formed on the silicon dioxide gate insulating film 9 by using the solution in which the TTF and the nanoparticles are dissolved as shown in FIG. 21. The self-organized nanoparticle array 15 contains not only the gold nanoparticles 5 but also the TTF molecules, and the amount of the TTF molecules is controlled so that the number of nanoparticles can be almost equal to that of the TTF molecules.

Subsequently, a gold source electrode 10 and a gold drain electrode 11 are formed on the self-organized nanoparticle array 15 by using the photolithography process and the lift-off process, thereby completing the top-contact Mott transistor. As a material of the source and drain electrodes, materials other than gold is also available. However, gold has an advantage that it can easily make the contact in comparison to other materials.

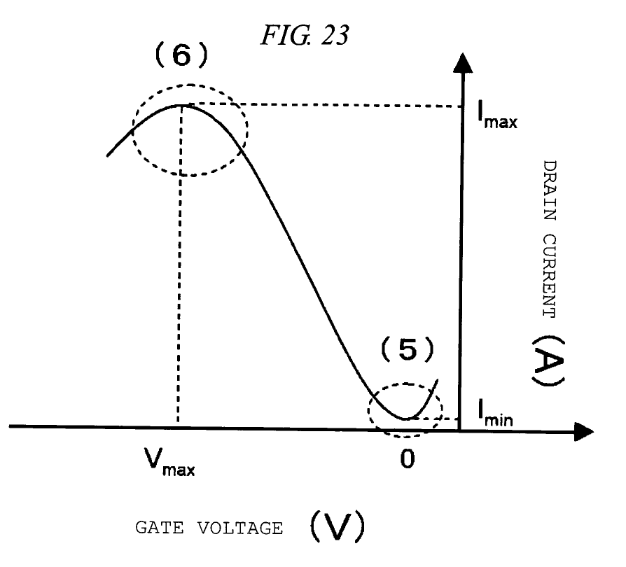

The device characteristics of the Mott transistor manufactured in the manner as described above are shown in FIG. 23. The voltage of 20 V is applied between the source and drain. In an area (5) in which the gate voltage is low, the drain current is also low, and it can be understood that the normally off is achieved. This state is the Mott insulator state shown in FIG. 3 and corresponds to the state (3) in FIG. 16. Here, as the negative gate voltage is applied, the drain current is increased and reaches the maximum in (6). This state is the metal state shown in FIG. 2 and corresponds to the state (2) in FIG. 16. Therefore, it can be understood that the Vmin in FIG. 16 can be parallelly shifted to the position near 0 V by doping the TTF molecules in FIG. 23. Therefore, it becomes apparent that it is possible to control the threshold value by the doping. Since the Mott transition is a phase transition phenomenon, the change in current value is extremely sharp. Although the number of nanoparticles and that of the TTF molecules are controlled to be almost equal to each other in this embodiment, the threshold value of the device characteristics can be optionally controlled by changing the number of TTF molecules.

In addition to the improved device characteristics described above, since the Mott transistor is formed on a plastic substrate in this embodiment, the substrate itself can be bent. Also, since a current as a driving current higher than that obtained from a standard organic transistor made of a organic semiconductor can be obtained, it is suitable for the transistor for driving the organic EL to realize a so-called electronic paper whose display is bendable.

### Third Embodiment

This embodiment discloses the method in which an organic semiconductor is bonded to the periphery of the metal nanoparticles so that the effective mobility of the field effect transistor in which the self-aligned nanoparticle array bonded by the organic semiconductor is used for a channel can be increased about ten times.

At the beginning, the nanoparticles used in this embodiment are formed. First, hydrogen tetrachloroaurate (III) tetrahydrate of 0.37 g is dissolved into the water of 30 ml. Then, chloroform of 80 ml is added to the solution and tetra-n-octyl ammonium bromide of 2.2 g is added thereto. Thereafter, the solution is stirred for an hour at a room temperature. Then, poly(3-hexyl thiophene) of 0.28 g is added to the solution and the resulting solution is stirred for an hour. Further, sodium borohydride of 0.38 g is dissolved into the water of 25 ml and this solution is dropped into the above-described solution in 30 minutes, and the resulting solution is stirred for five hours. The solution is separated and an organic layer is concentrated to 10 ml. Then, ethanol of 400 ml is added thereto and the resulting solution is left sitting for 50 hours at −18° C. Thereafter, it is dried under the reduced pressure after removing the supernautant liquid. In this manner, gold nanoparticles in dark brown of 0.25 g whose surface is protected by polythiophene can be obtained. The average particle diameter of the nano-fine particles is 3.8 nm. Since the sulfur atoms of polythiophene and the gold atoms are bonded, the central portion is covered with polythiophene.

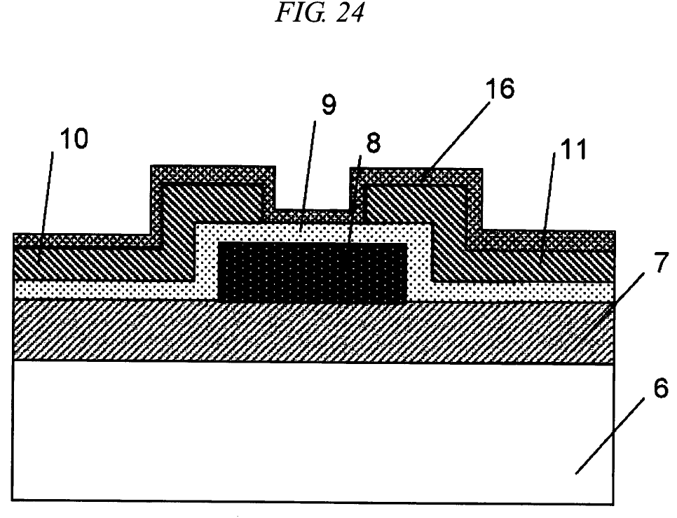

Next, the gate electrode 8, the silicon dioxide gate insulating film 9, the gold source electrode 10, and the gold drain electrode 11 are formed on a silicon substrate in the same manner as that described in the first embodiment, thereby forming the structure shown in FIG. 8. In this embodiment, a silicon substrate is used as the substrate so as to facilitate the formation of the device. However, it is also possible to use a flexible plastic substrate used in the second embodiment. Subsequently, a mono-layer is formed with using the gold nano-fine particles 16 whose surface is protected by the polythiophene as an LB film as shown in FIG. 24.

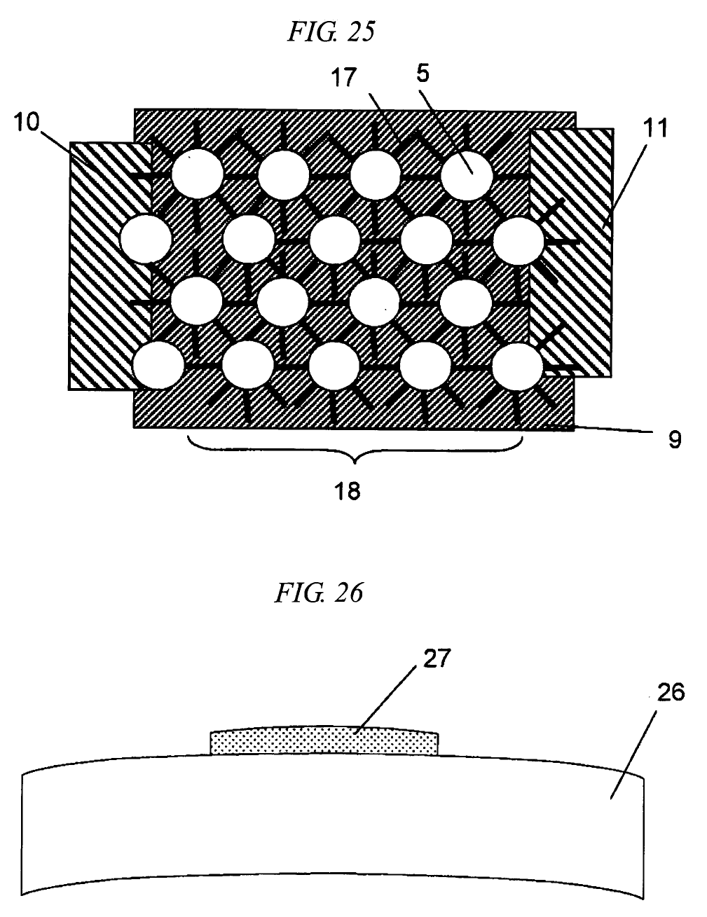

Next, the entire chip is dipped into a solution of sodium borohydride with a concentration of 0.4 mol/l for 24 hours. As a result, the self-organized nanoparticle array 18 in which a plurality of gold nanoparticles are bonded in a matrix form by the polythiophene 17 can be formed as shown in FIG. 25. By doing so, the field effect transistor in which the self-organized nanoparticle array bonded by the organic semiconductor is used as the channel can be completed. When forming a circuit, desired wirings are formed thereafter.

As the organic semiconductor molecules, pentacene, naphthalene, and copper phthalocyanine are also available in addition to polythiophene.

The field effect transistor formed in the manner as described above is a pMOS operated on the storage side. It is known that the Fermi level of polythiophene is present close to the valence band even without the intentional doping, and it is possible to achieve the normally off. Even in the case where the gold nanoparticles are bonded like in this embodiment, the transistor is operated as a pMOS and it is possible to achieve the normally off.

The effective mobility of this device is about 1.0 cm²/Vs. This is ten times larger than that of the conventional organic transistor whose channel portion is formed of only polythiophene without using the metal nanoparticles. This is because the hopping of holes through the polythiophene molecules is made easier when polythiophene molecules are bonded by the metal nanoparticles. Therefore, it is possible to effectively increase the mobility of the field effect transistor by bonding the metal nanoparticles to the organic semiconductor.

The examples of the transistors in the first to third embodiments have the channel portion formed on a gate electrode. However, the transistor not having the channel portion formed on the gate electrode is also available. For example, the transistor having the channel portion formed below the gate electrode and that having the channel portion formed vertically to the substrate are also available.

1. A field effect transistor comprising:
a gate electrode;
a pair of source and drain electrodes; and
a channel portion,
wherein said channel portion contains particles of metal or semiconductor and organic molecules which cover said particles.

2. The field effect transistor according to claim 1,
wherein a diameter of said particles is 10 nm or smaller.

3. The field effect transistor according to claim 1,
wherein a number of said molecules are provided and the shortest length between particle surfaces is 4 nm or shorter.

4. The field effect transistor according to claim 1,
wherein said organic molecules have a thiol group.

5. The field effect transistor according to claim 1,
wherein a number of said molecules are provided and an array of said particles has a close-packed structure.

6. The field effect transistor according to claim 1,
wherein said particles include gold, silver, platinum, or some of these elements.

7. The field effect transistor according to claim 1,
wherein said particles include copper, aluminum, tin, silicon, cadmium, or selenium.

8. A field effect transistor comprising:
a gate electrode;
a pair of source and drain electrodes; and
a channel portion,
wherein said channel portion contains particles of metal or semiconductor, organic molecules which cover said particles, and an ionized polarizing material.

9. The field effect transistor according to claim 8,
wherein a diameter of said particles is 10 nm or smaller.

10. The field effect transistor according to claim 8,
wherein a number of said molecules are provided and the shortest length between particle surfaces is 4 nm or shorter.

11. The field effect transistor according to claim 8,
wherein said organic molecules have a thiol group.

12. The field effect transistor according to claim 8,
wherein a number of said molecules are provided and an array of said particles has a close-packed structure.

13. The field effect transistor according to claim 8,
wherein said particles include at least one of gold, silver, and platinum.

14. The field effect transistor according to claim 8,
wherein said particles include copper, aluminum, tin, silicon, cadmium, or selenium.

15. The field effect transistor according to claim 8,
wherein said ionized polarizing materials are TTF molecules, Ce(SO₄)₂, alkali metal, alkaline earth metal, I₂, Br₂, Cl₂, AsF₅, or BF₃ or include some of these materials.

16. A field effect transistor comprising:
a gate electrode;
a pair of source and drain electrodes; and
a channel portion,
wherein said channel portion contains particles of metal or semiconductor, organic molecules which cover said particles, and organic semiconductor molecules.

17. The field effect transistor according to claim 16,
wherein said organic semiconductor molecules are polythiophene, pentacene, naphthalene, or copper phthalocyanine.

18-23. (canceled)
